(19) United States
(12) Patent Application Publication
(10) Pub. No.: US 2013/0148286 A1
(43) Pub. Date: Jun. 13, 2013

(54) MOUNTING DEVICE FOR EXPANSION CARD

(71) Applicants: LEI LIU, Shenzhen City (CN); WEI-DONG CONG, Shenzhen City (CN)

(72) Inventors: LEI LIU, Shenzhen City (CN); WEI-DONG CONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/330,560

(22) Filed: Dec. 19, 2011

(30) Foreign Application Priority Data
Dec. 13, 2011 (CN) 201110414457.3

(51) Int. Cl. G06F 1/16; H05K 7/00

(52) U.S. Cl. 361/679.32; 248/205.1; 248/225.21

(57) ABSTRACT

A mounting device for an expansion card includes a circuit board, a rail mounted on the circuit board, and a latch slidably mounted to the rail. A front end of the expansion card is fixed to a sidewall of a chassis. The latch includes a clamping portion to hold and support a rear end of the expansion card.

### BACKGROUND

1. Technical Field

The present disclosure relates to a device for mounting an expansion card.

2. Description of Related Art

In installing an expansion card, one end of the expansion card is generally fixed to a chassis, while an opposite end of the expansion cards is cantilevered. As a result, when an expansion card is long and horizontally fixed to the chassis, the cantilevered end may droop and cause damage to the expansion cards.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device with an expansion card; wherein the mounting device includes a rail.

FIG. 2 is an inverted view of the rail of FIG. 1.

FIG. 3 is an assembled, isometric view of the mounting device of FIG. 1, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

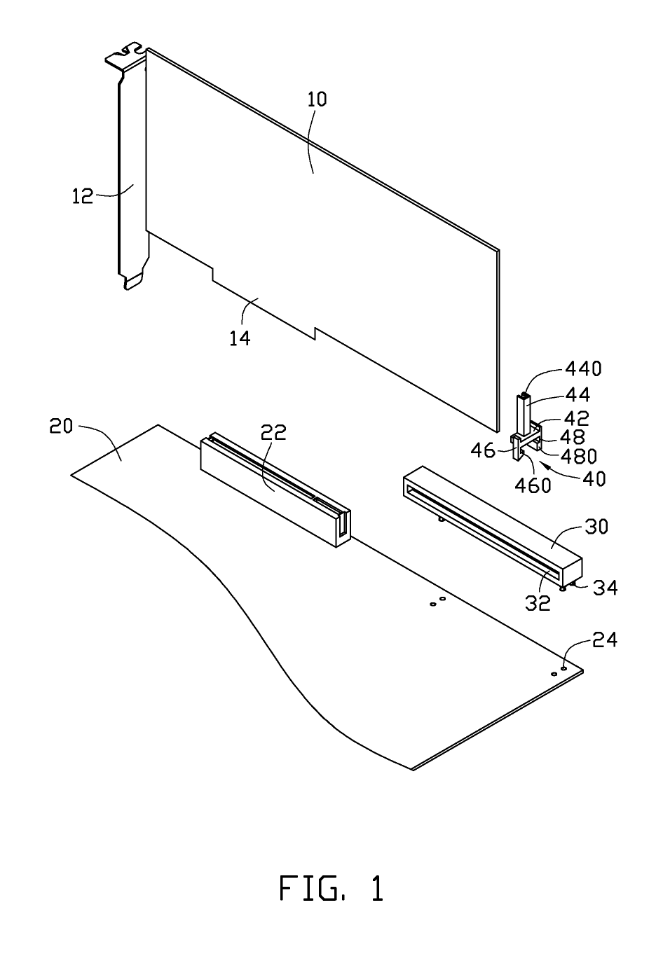

Referring to FIG. 1, an exemplary embodiment of a mounting device for an expansion card 10 includes a circuit board 20 mounted in a chassis (not shown), a rail 30, and a latch 40.

An L-shaped fixing piece 12 is fixed to a first end of the expansion card 10. An edge connector 14 extends down from a bottom side of the expansion card 10.

A connector 22 is formed on a top surface of the circuit board 20. A plurality of through holes 24 is defined in the circuit board 20, aligning with the connector 22.

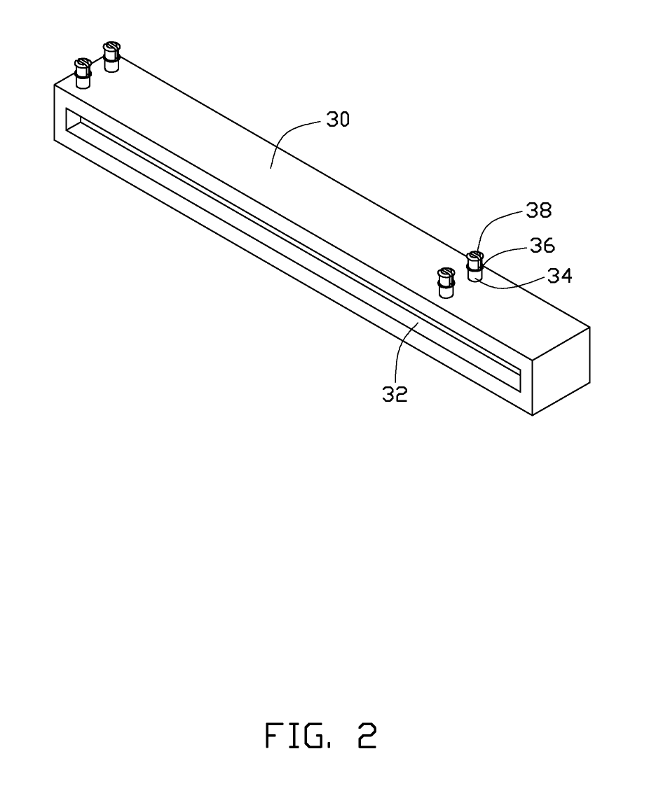

Referring to FIG. 2, the rail 30 is rectangular, and longitudinally defines two lateral slots 32 in opposite sides of the rail 30. A plurality of columnar pins 34 extends down from a bottom surface of the rail 30. An annular blocking portion 36 protrudes from the circumference of a distal end of each pin 34 opposite to the rail 30. Two deformable hooks 38 extend down from the distal end of each pin 34 away from the blocking portion 36.

The latch 40 includes a connection portion 42, a U-shaped clamping portion 44 perpendicularly extending up from a top of the connection portion 42, an engaging portion 46 and a sliding portion 48 extending down from opposite ends of the connection portion 42. A clamping slot 440 is defined in a side surface of the clamping portion 44 and extends up through a top end of the clamping portion 44. A top of the engaging portion 46 protrudes over the connection portion 42, to function as an operation portion for deforming the engaging portion 46. A projection 460 and a protrusion 480 extend towards each other from the bottom end of the engaging portion 46 and the bottom end of the sliding portion 48 opposite to the clamping portion 44. The projection 460 and a protrusion 480 work together in the manner of pincers. The engaging portion 46 is made of plastic, and is deformable. In another embodiment, the sliding portion 48 may be replaced by an engaging portion 46.

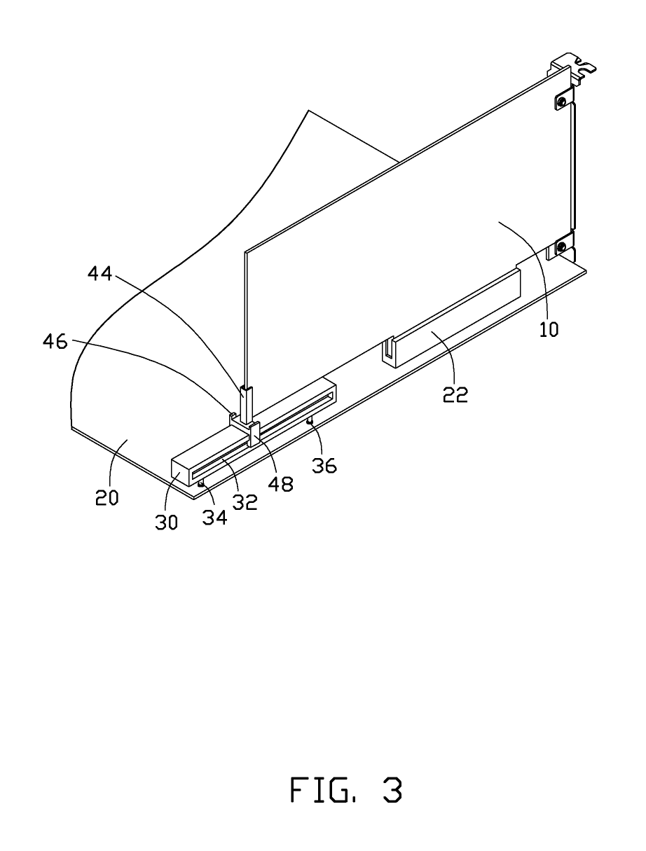

Referring to FIG. 3, in assembly, the hooks 38 of each pin 34 are deformed toward each other to be manipulated through the through holes 24. After the hooks 38 are released, the hooks 38 are blocked by a bottom surface of the circuit board 20, thereby mounting and locking the rail 30 to the circuit board 20. The blocking portions 36 are blocked by the top surface of the circuit board 20, allowing a space between the rail 30 and the circuit board 20. The top of the engaging portion 46 is pressed toward the sliding portion 48 to deform the projection 460 away from the protrusion 480. After the protrusion 480 is slidably engaged in one of the slots 32 by downward fingertip pressure, the projection 460 self-restores into the other slot 32, thereby firmly mounting the latch 40 to the rail 30. The clamping slot 440 faces the connector 22.

In use, the fixing piece 12 is fixed to a sidewall of the chassis. The edge connector 14 is inserted into the connector 22. The top of the engaging portion 46 is pressed toward the sliding portion 48 again to disengage or at least loosen the projection 460 from the slot 32. The protrusion 480 is slid toward the expansion card 10 until a second end of the expansion card 10 opposite to the fixing piece 12 is engaged by the clamping slot 440. The projection 460 is then allowed to self-restore to once again engage in the corresponding slot 32, thereby fixing and providing permanent support to the second end of the expansion card 10.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for positioning an end of an expansion card, the mounting device comprising:
a rail to be mounted on a circuit board and at the end of the expansion card; and
a latch mounted to the rail and slidable along a direction parallel to the expansion card, and comprising a clamping portion for clamping the end of the expansion card.

2. The mounting device of claim 1, wherein a plurality of pins extends down from the rail to engage in the circuit board.

3. The mounting device of claim 2, wherein a deformable hook extends down from a distal end of each hook to be extended through the circuit board and blocked by a bottom surface of the circuit board.

4. The mounting device of claim 2, wherein a blocking portion protrudes from a circumference of each pin to abut against a top surface of the circuit board.

5. The mounting device of claim 1, wherein the rail longitudinally defines two slots in opposite sides along a direction parallel to the expansion card, the latch further comprises a connection portion connected to a bottom end of the clamping portion, a deformable engaging portion and a sliding portion extend down from opposite ends of the connection portion, a projection and a protrusion extend toward each other respectively from distal ends of the engaging portion and the sliding portion, the protrusion is slidably engaged in one of the slots, the engaging portion is operable to be deformed, thereby making the projection engage in or disengage from the other slot.

6. The mounting device of claim 1, wherein a clamping slot is defined in a side surface of the clamping portion to clamp the end of the expansion card.

7. A mounting device for an expansion card, the mounting device comprising:
a circuit board comprising a connector for connecting an edge connector of the expansion card;
a rail mounted on the circuit board and aligning with the connector; and
a latch slidably mounted to the rail and comprising a clamping portion for clamping an end of the expansion card.

8. The mounting device of claim 7, wherein a plurality of through holes is defined in the circuit board, a plurality of pins extends down from the rail, a deformable hook extends down from a distal end of each hook opposite to the rail to be extended through a corresponding one of the through holes and blocked by a bottom surface of the circuit board

9. The mounting device of claim 8, wherein a blocking portion protrudes from the circumference of each pin and abuts against a top surface of the circuit board to allow the rail space from the circuit board.

10. The mounting device of claim 7, wherein the rail longitudinally defines two slots in opposite sides, the latch further comprises a connection portion connected to a bottom end of the clamping portion, an deformable engaging portion and a sliding portion extend down from opposite ends of the connection portion, a projection and a protrusion extend toward each other respectively from distal ends of the engaging portion and the sliding portion, the protrusion is slidably engaged in one of the slots, the projection is operable to engaged in or disengage from the other slot.

11. The mounting device of claim 7, wherein a clamping slot is defined in a side surface of the clamping portion to clamp the end of the expansion card.
